(19) United States
(12) Patent Application Publication
(10) Pub. No.: US 2026/0304730 A1
(43) Pub. Date: Oct. 1, 2026

(54) Interlocking Cell-Pair Layout of Buffered Read Port Static Random-Access Memory (SRAM) with P and N Pass Gates to Same Write Bit Line

(71) Applicant: Aril Computer Corporation, Los Altos, CA (US)

(72) Inventors: Sinan Doluca, Saratoga, CA (US); Thomas Riordan, Los Altos, CA (US)

(73) Assignee: Aril Computer Corporation, Los Altos, CA (US)

(21) Appl. No.: 19/702,031

(22) Filed: Jun. 9, 2026

Related U.S. Application Data
(63) Continuation-in-part of application No. 18/671,872, filed on May 22, 2024, now Pat. No. 12,731,637.

(51) Int. Cl. H10B 10/00

(52) U.S. Cl. CPC H10B 10/125

(57) ABSTRACT

A multi-port memory cell has a writable cell and a buffered read port. The writable cell has cross-coupled inverters and transmission gates to write bit lines. Each transmission gate has n-channel and p-channel transistors in parallel that both turn on during writing. The gate polysilicon of a cross-coupled inverter is extended to form gates of data transistors in the buffered read port. The writable cell is laid out in a first rectangle that abuts a second rectangle having the buffered read port. The second rectangle is half of the area of the first rectangle, forming an L-shaped cell layout. Even and odd cell layouts are interlocked by placing buffered read ports for both even and odd cells next to each other, between the two writable cells. Second rectangles of the even and odd cells are placed together between the first rectangles of the even and odd cells.

### FIELD OF THE INVENTION

This invention relates to layouts of Static Random-Access Memory (SRAM), and more particularly to interlocking pairs of cell layouts.

### BACKGROUND OF THE INVENTION

Semiconductor memories such as Static Random-Access Memory (SRAM) scale their supply voltages as cell transistors shrink in size with improving semiconductor processing technologies. A traditional SRAM cell has four transistors that form a latch that stores a bit of data, and two pass transistors that connect the latch to a pair of bit lines. Both reading and writing of the cell are performed through these pass transistors in the traditional six-transistor 6T SRAM cell.

Scaling of supply voltage has been possible in advanced node Complementary Metal-Oxide-Semiconductor (CMOS) Fin Field-Effect Transistor (FinFET) processes by trading off performance and clock frequency against power consumption. Dynamic voltage scaling and frequency scaling can be used to optimize performance and power consumption.

Supply-voltage scaling problems can occur due to read signal margin and write signal margin requirements. To improve these margin requirements, some semiconductor foundries require a higher memory supply voltage (VDDM) to SRAM building blocks than the supply voltage to other logic (VDD).

SRAMs are sometimes available as a macro cell in a standard cell or similar design library. Ideally, the SRAM should use the same supply voltage (VDD) as the logic cells in the macro library. Additional voltage conversion circuits are needed when the SRAM has a different supply voltage. These additional voltage conversion circuits are undesirable.

In some cases, designers have chosen to use latches with buffered read access ports to design Ultra-Low-Voltage (ULV) SRAM macros. The tradeoff is that layout area is compromised for voltage scaling capability.

SRAM cells with multiple ports are sometimes needed in standard cell designs. While a traditional 6T SRAM cell has a shared read/write port that uses the same pass transistors and bit lines for both reading and writing, other multiport SRAM cells have separate transistors and bit lines for reading and writing.

For example, a traditional 8 transistor (8T) SRAM cell has 1 Read port and 1 Write port (1R1W). Reading is performed through separate transistors and bit lines that are not used for writing. Voltage scaling is limited due to writability of the cell at low voltages. The cell is very NMOS dominant with 6 NMOS and 2 PMOS devices. This imbalance leads to a less-than-optimum footprint in layout area.

Not all SRAM cell structures are a good fit for the transistor layout footprint used by standard cell or macro libraries. These library cells are optimized for logic cells. Logic cells tend to have an equal number of p-channel (PMOS) and n-channel (NMOS) transistors. Thus the area in the layout that is allocated for macro cells tend to allow for an equal number of NMOS and PMOS transistors. If a standard all-NMOS 6T SRAM cell is used, with 6 NMOS and no PMOS transistors, the area reserved for PMOS can be wasted.

The additional read port of a 1R1W multi-port SRAM cell may have fewer transistors than the storage node/write port. For example, the 1R1W cell in FIG. 1 has 8 transistors (8T) in write-only RAM cell 10, but only 4 transistors (4T) in buffered read port 31. This imbalance in the number of transistors in 8T write cell 10 and 4T buffered read port 31 may lead to layout imbalances. Cell 10 has more transistors and occupies more area than buffered read port 31. Fitting both SRAM cell 10 and buffered read port 31 in the same layout footprint is challenging and may lead to wasted area.

What is desired is a multi-port SRAM cell that has a circuit schematic and a layout that are optimized for standard cell macro libraries. A SRAM cell with an equal number of PMOS and NMOS transistors is desired to better fit into the layout of logic cells in a standard cell library. A balanced PMOS/NMOS SRAM cell that can operate at ultra-low supply voltages is desirable. A multi-port SRAM cell with a buffered read port to read bit lines, and a separate write port with both NMOS and PMOS pass transistors to the write bit lines is desired to allow for full CMOS complimentary writing into the cell, even at very low voltages. A balanced PMOS/NMOS multi-port 1R1W SRAM cell that does not require external read or write assist circuitry is desired.

### BRIEF DESCRIPTION OF THE DRAWINGS

FIG. 1 is a diagram of a multiport SRAM cell with a write-only RAM with both P and N transistors in parallel to write bit lines, and a buffered read port to a read data line.

FIG. 2 is a schematic of a write-only RAM cell with a buffered read port having an inverter and a transmission gate.

FIG. 3 is a schematic diagram of a write-only RAM cell with a tri-state buffer read port.

FIG. 4 is a schematic of the write-only RAM cell with the buffered read port that is drawn to match the proposed layout.

FIG. 5 shows outlines of the interlocked pair of L-shaped 1R1W cell layouts.

FIG. 6 shows a simplified layout of an even-odd pair of 1R1W cells for a non-stacked process.

FIG. 7 shows an alternative layout without the metal short line in the buffered read port.

FIG. 8 shows 3D structures made from semiconductor materials that form transistor channels between source and drain regions.

FIG. 9 shows a Gate-All-Around (GAA) transistor.

FIG. 10 shows stacked GAA transistors.

FIG. 11 is a simplified layout of the even-odd pair of 1R1W cells for a stacked-transistor process.

FIGS. 12A-D are cross sectional slices through the pair of 1R1W cells of FIG. 11.

### DETAILED DESCRIPTION

The present invention relates to an improvement in multi-port SRAM cell layouts. The following description is presented to enable one of ordinary skill in the art to make and use the invention as provided in the context of a particular application and its requirements. Various modifications to the preferred embodiment will be apparent to those with skill in the art, and the general principles defined herein may be applied to other embodiments. Therefore, the present invention is not intended to be limited to the particular embodiments shown and described, but is to be accorded the widest scope consistent with the principles and novel features herein disclosed.

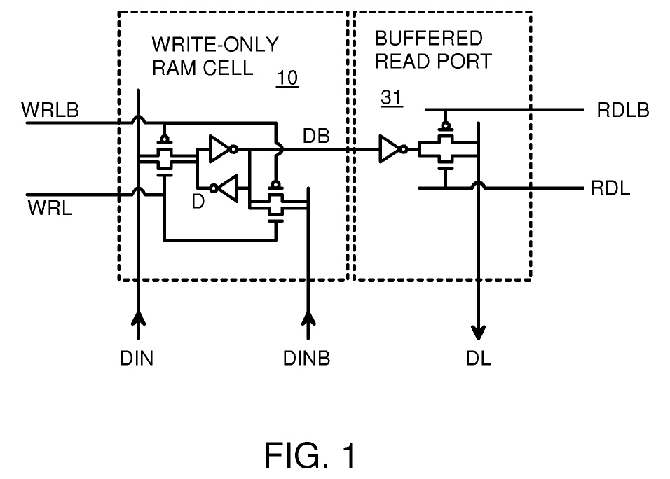

The parent application, U.S. Ser. No. 18/671,872, now U.S. Patent No. __________________ , disclosed a 1R1W multiport SRAM cell with an equal number of p-channel and n-channel transistors. FIGS. 1-3, described below, are from the parent application.

FIG. 1 is a diagram of a multiport SRAM cell with a write-only RAM with both P and N transistors in parallel to write bit lines, and a buffered read port to a read data line. Cell 10 stores one bit of data D in a latch created by cross-coupled inverters. Cell 10 is written when the row is selected by Write Row Line (WRL) being high and WRLB being low. WRLB is the inverse of WRL. WRL high turns on the n-channel pass transistors and WRLB low turns on the p-channel pass transistors, so all four pass transistors are turned on when writing. The input data on write bit line DIN drives through both n-channel and p-channel pass transistors to node D in the cell latch, while inverse input data on write bit line DINB drives through another pair of n-channel and p-channel pass transistors to inverse node DB in the cell latch. Thus the cell latch is written by differential data through two very low impedance transmission gates. This allows for a fast write even when ultra-low power-supply voltages are used. Cell write margin is very good.

The overall cell margin and stability is further enhanced by using buffered read port 31. A traditional read port has pass transistors from the cell latch to one or two read bit lines. When the read row is selected and the read pass transistors turn on, charge sharing occurs between the read bit lines and the cell latch. This charge sharing can disturb the cell latch, perhaps causing loss of the data being stored at the margin conditions.

Instead, in a simple embodiment buffered read port 31 has the cell latch’s inverse data node DB applied to the input of an inverter. Since the inverter input is typically the gates of a pair of n-channel and p-channel transistors, there is little or no charge sharing between buffered read port 31 and the cell latch in cell 10. The buffered data from the cell latch is driven by the inverter in buffered read port 31 through a pair of p-channel and n-channel transistors to a read data line DL when the read row is selected with RDL high and RDLB low.

Cell 10 is not directly read except through buffered read port 31, so cell 10 is a write-only RAM cell. Write-only RAM cell 10 and buffered read port 31 together form a 1R1W SRAM cell.

Note that writing and reading can be performed asynchronously to each other, and even simultaneously. Reads do not disturb the cell state in write-only RAM cell 10, so reads can occur at any time. If a read occurs just as a write is changing the state of write-only RAM cell 10, then the read can return unstable data, but this is the actual data state of write-only RAM cell 10 as it is changing state.

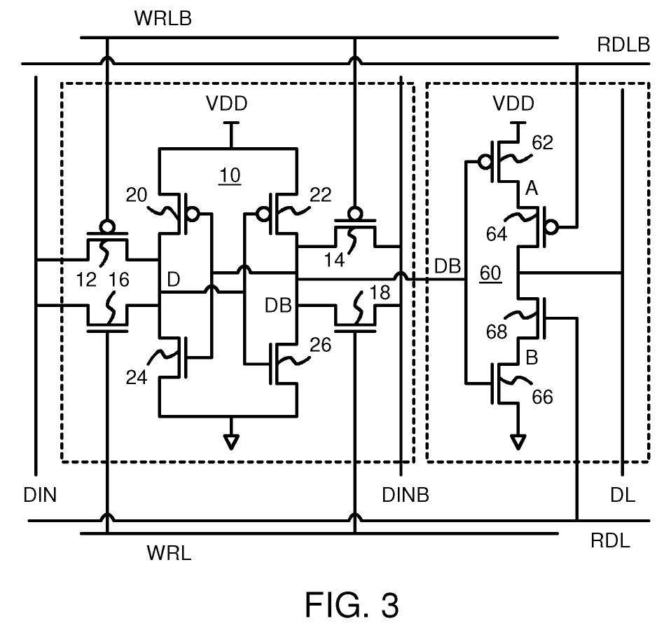

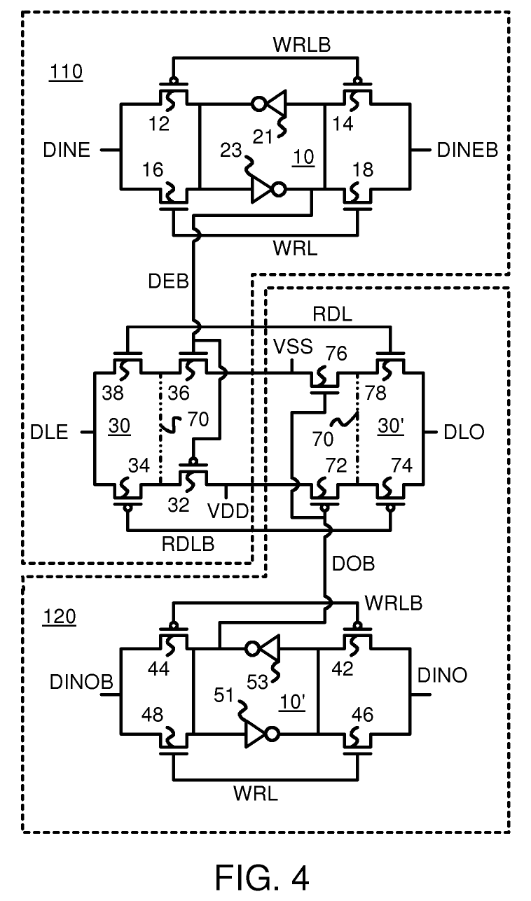

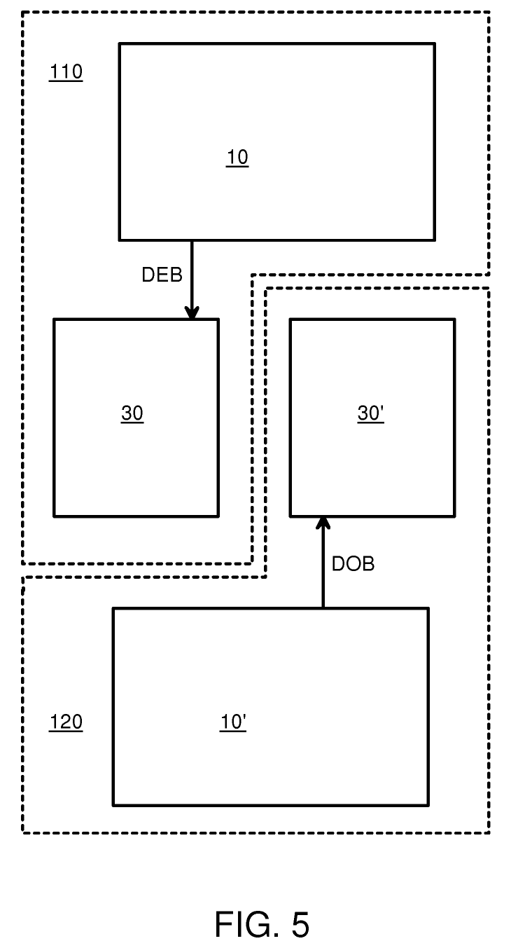

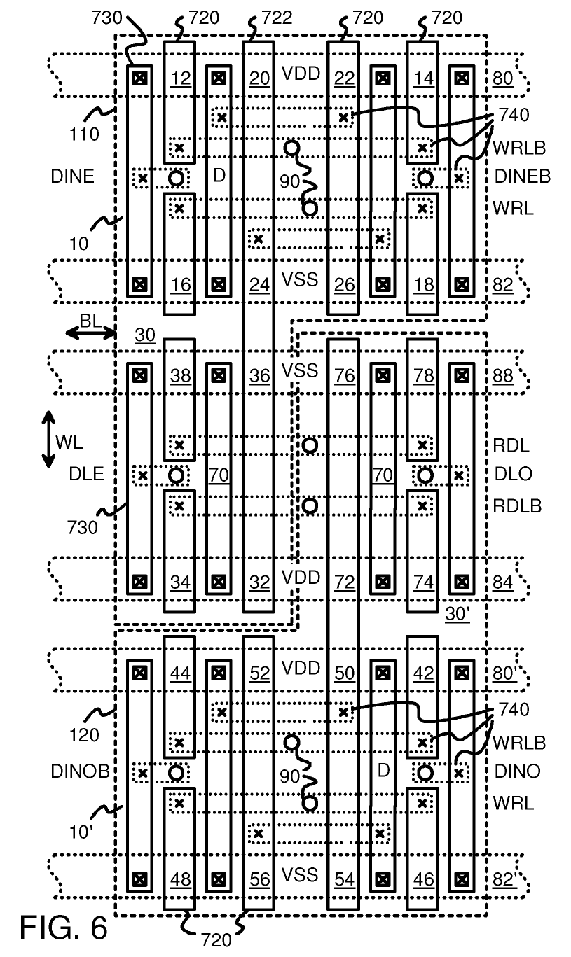

In its simplest form, buffered read port 31 can be an inverter and a transmission gate. Other forms of buffered read port 31, such as shown in FIGS. 3-4, also do not disturb write-only RAM cell 10 because they only receive cell nodes D or DB on the gates of transistors, thus preventing charge sharing with the latch. Three-port and larger cells can be constructed by having two or more instances of buffered read port 31 for each write-only RAM cell 10, such as shown in FIGS. 5-6.

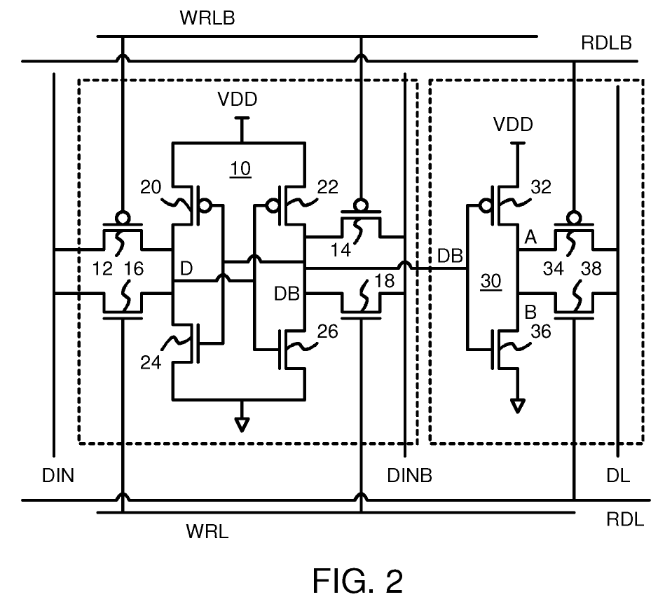

FIG. 2 is a schematic of a write-only RAM cell with a buffered read port having an inverter and a transmission gate. Write-only RAM cell 10 stores a bit of data D in a latch formed by two inverters.

The drains of p-channel transistor 20 and n-channel transistor 24 are connected together at data node D and to the gates of p-channel transistor 22 and n-channel transistor 26, which have their drains connected together and to the gates of p-channel transistor 20 and n-channel transistor 24, forming a pair of cross-coupled inverters. The drains of transistors 22, 26 drive the inverse data node DB of the cell latch. The sources of n-channel transistors 24, 26 connect to ground, while the sources of p-channel transistors 20, 22 connect to the power supply VDD. VDD is the same ultra-low voltage supply used by the logic gates and macros in a standard cell design.

As with a traditional 6T SRAM cell, only a single pair of bit lines DIN, DINB, connect to write-only RAM cell 10. However, full transmission gates are provided to connect the cell latch to the write bit lines DIN, DINB.

During a write operation, write word line WRLB drives the gates of p-channel pass transistors 12, 14 low, allowing bit line DIN to drive the drains of transistors 20, 24 through p-channel pass transistor 12, and allowing complementary bit line DINB to drive the drains of transistors 22, 26 through p-channel pass transistor 14, thus writing data into cell 10.

To improve the write margin, both P and N pass transistors are turned on for a write, so that p-channel pass transistor 12 and n-channel pass transistor 16 act as a transmission gate between the cell latch and bit line DIN. Likewise, p-channel pass transistor 14 and n-channel pass transistor 18 act as a transmission gate to DINB.

During a write, write word line WRL is activated by driving it high, and inverse write word line WRLB is also activated by driving it low, so that all pass transistors 12, 14, 16, 18 are turned on.

Reading is performed by buffered read port 30. Write-only RAM cell 10 is not capable of performing a read operation since no sense amplifiers or read circuitry is attached to the write bit lines DIN, DINB. Write bit line DIN is driven with the write data by a bit-line driver and inverse write bit line DINB is driven with the inverse write data by another bit-line driver. Write row line WRL is only activated during a valid write operation and is not activated for a read operation. Thus pass transistors 12, 14, 16, 18 only turn on during a valid write operation and remain off during reads to isolate the latch inside write-only RAM cell 10.

The inverse data node DB from the latch in write-only RAM cell 10 is applied to the gates of p-channel transistor 32 and n-channel transistor 36, which form an inverter that buffers inverse node DB from the read bit line DL. The drains of transistors 32, 36 connect together and to the transmission gate. The transmission gate has n-channel transistor 38 and p-channel transistor 34 in parallel between the inverter output, the drains of transistors 32, 36, and the read bit line DL.

During a read operation, a row is selected by driving read row line RDL high and inverse read row line RDLB low. All other non-selected rows in the array are disabled by having their RDL low and RDLB high. RDL high is applied to the gate of n-channel transistor 38, turning it on, while RDLB low is applied to the gate of p-channel transistor 34, turning it on. With both transistors 34, 38 on, a low-impedance path is provided, allowing the inverter (drains of transistors 32, 36) to drive read bit line DL.

The read speed can be faster using a full transmission gate than using only a n-channel transistor, especially for high data. A second read bit line and differential sensing is not needed since the inverter can rapidly drive the single read bit line DL through the low-impedance transmission gate. Thus read sensing circuitry around the memory cell array can be less complex.

The overall cell is symmetric and does not require dummy transistors. There are 6 NMOS transistors and 6 PMOS transistors for a total of 12 transistors (12T). Write-only RAM cell 10 has 8 transistors while buffered read port 30 has 4 transistors. The overall cell uses only VDD, which is applied to the sources of p-channel transistors 20, 22, 32.

FIG. 3 is a schematic diagram of a write-only RAM cell with a tri-state buffer read port. In this variation, buffered read port 60 has a tri-state inverter. The transmission gate is integrated into the inverter. Write-only RAM cell 10 is the same as described for FIG. 2.

Buffered read port 60 has a single logic gate that receives inverse data node DB on the gates of p-channel transistor 62 and n-channel transistor 66. The source of p-channel transistor 62 is connected to VDD, while its drain connects to the source of p-channel transistor 64. The gate of p-channel transistor 64 is the inverse read row line RDLB, and its drain is read bit line DL.

Similarly, the source of n-channel transistor 66 is connected to ground, while its drain connects to the source of n-channel transistor 68. The gate of n-channel transistor 68 is the read row line RDL, and its drain is read bit line DL.

When the current row is not selected, or when reading is not occurring, RDL is low and RDLB is high, turning off transistors 68, 64 and isolating buffered read port 60 from read bit line DL.

When the current row is selected during a read operation, RDL is high, turning on n-channel transistor 68. RDLB is low, turning on p-channel transistor 64. Then the inverse data DB from the latch inside write-only RAM cell 10 can drive data onto read data line DL. When DB is low, p-channel transistor 62 turns on, driving DL high through p-channel transistor 64. When DB is high, n-channel transistor 66 turns on, driving DL low through n-channel transistor 66. Thus the inverted cell data DB is inverted again through buffered read port 60.

Buffered read port 60 (FIG. 3) and buffered read port 30 (FIG. 2) are considered static read ports since the read bit line is driven both high and low. Precharging of the read bit line is not required for the correct data to be read eventually.

Note that buffered read port 60 (FIG. 3) and buffered read port 30 (FIG. 2) are nearly identical, except that nodes A and B are separate in FIG. 3, but are shorted together in FIG. 2. A standard cell could be designed to have an option to short nodes A and B together when buffered read port 30 is desired, but to not short nodes A and B together when buffered read port 60 is desired. The option could be a piece of metal that connects a contact to the diffusion for node A to a contact to the diffusion for node B.

The inventors have realized that the write-only RAM cell with the buffered read port of FIGS. 1-3 is inherently imbalanced. 8T SRAM cell 10 has twice as many transistors as does 4T buffered read port 31. While the overall 12T cell has an equal number of n-channel and p-channel transistors, layout can be challenging because write-only SRAM cell 10 is roughly twice the size of buffered read port 31. Sharing control signals with adjacent cells can improve cell layout efficiency, but the control signals for write-only SRAM cell 10 are different than the control signals for buffered read port 31. For example, write-only SRAM cell 10 has write row line control signals WRL, WRLB that are not used by buffered read port 31, while buffered read port 31 has read row line control signals RDL, RDLB that are not used by write-only SRAM cell 10. Also, write-only SRAM cell 10 connects to bit lines DIN, DINB, while buffered read port 31 connects to data line DL. Thus the interconnect is different for write-only SRAM cell 10 and for buffered read port 31.

The inventors further realize that cell internal node DB is the only interconnect between write-only SRAM cell 10 and buffered read port 31 within the write-only RAM cell with the buffered read port. Write-only SRAM cell 10 can be laid out adjacent to but otherwise separate from buffered read port 31.

The inventors further realize that 4T buffered read port 31 is half the size of 8T write-only SRAM cell 10, so the 1R1W SRAM cell is inherently L-shaped rather than rectangular, with a wide end for write-only SRAM cell 10 and a smaller end for buffered read port 31.

The inventors realize that a pair of buffered read ports 31 could fit in the adjacent footprint of each write-only SRAM cell 10. The width or pitch of write-only SRAM cell 10 can fit two buffered read ports 31. Thus two L-shaped 1R1W SRAM cells could be fitted together to fill a larger, double-sized rectangular space. Two interlocking L-shaped 1R1W SRAM cells can be laid out together as a cell pair that forms a rectangular footprint that easily can be arrayed into rows and columns.

FIG. 4 is a schematic of the write-only RAM cell with the buffered read port that is drawn to match the proposed layout. The locations of transistors in FIG. 4 is approximately where these transistors are located in the cell layout. The schematic of FIG. 4 would be arrayed in the x and y directions.

The cell layouts in FIGS. 4-11 are rotated by 90 degrees so that the row or x word lines run vertically and the column or y bit lines and data lines run horizontally. This rotation is needed to match standard cell layouts where data flows in the horizontal direction.

FIG. 4 shows a pair of the write-only RAM cell with the buffered read port. The pair includes 1R1W cell 110 and 1R1W cell 120. 1R1W cell 110 has a wide top of write-only SRAM cell 10, and a half-width bottom of buffered read port 30, with internal node DEB being the only interconnecting signal between write-only SRAM cell 10 and buffered read port 30. 1R1W cell 110 has an L-shape.

1R1W cell 120 also has a wide section for write-only SRAM cell 10’ and a narrow section for buffered read port 30’. Internal signal DOB is the only internal interconnect between write-only SRAM cell 10’ and buffered read port 30’ in odd 1R1W cell 120. 1R1W cell 120 also forms an L-shape.

Odd 1R1W cell 120 has buffered read port 30’ above write-only SRAM cell 10’ while even 1R1W cell 110 has its buffered read port 30 below write-only SRAM cell 10, allowing two buffered read ports 30, 30’ to fit together in the same pitch as one write-only SRAM cell 10. This alternating direction of intra-cell interconnect DEB, DOB causes the small ends of the L shaped cells 110, 120 to face each other, allowing L-shaped cells 110, 120 to fit together as a pair interlocking L-shaped cells.

Even write-only SRAM cell 10 has transistors 12, 14, 16, 18 and cross-coupled inverters 21, 23, which have transistors 20, 24, and 22, 26, respectively. Node DEB connects to even buffered read port 30, which has transistors 32, 34, 36, 38.

Odd write-only SRAM cell 10’ has transistors 42, 44, 46, 48 and cross-coupled inverters 51, 53, which have transistors 50, 54, and 52, 56, respectively. Node DOB connects to odd buffered read port 30’, which has transistors 72, 74, 76, 78.

Metal option lines 70 short nodes A, B together for the transmission gate of FIG. 2 or are disconnected for the tri-state buffer of FIG. 3 in the buffered read port.

In the rotated layout view of FIGS. 4-11, even 1R1W cell 110 and odd 1R1W cell 120 are in the same (shown vertically) row but are in different (horizontal) columns.

Even 1R1W cell 110 and odd 1R1W cell 120 share the same write-select word lines WRL, WRLB, and read select lines RDL, RDLB. Since the layouts are rotated, rows run vertically, and 1R1W cells 110, 120 are in the same row but are in different columns. Even bit lines DINE, DINEB and even read data line DLE connect to even 1R1W cell 110 while odd bit lines DINO, DINOB and odd read data line DLO connect to odd 1R1W cell 120.

N-channel transistors 16, 18 in write-only SRAM cell 10 face n-channel transistors 36, 38 and 76, 78 in buffered read ports 30, 30’. P-channel transistors 42, 44 in write-only SRAM cell 10’ face p-channel transistors 32, 34, 72, 74 in buffered read ports 30, 30’. Each pair of 1R1W cells 110, 120 can be flipped and/or rotated when building the array so that p-channel transistors face p-channel transistors in adjacent cells in the array to reduce area and to share power connections.

FIG. 5 shows outlines of the interlocked pair of L-shaped 1R1W cell layouts. Even 1R1W cell 110 has an L-shape because buffered read port 30 is half the pitch of write-only SRAM cell 10. Signal DEB from the cross-coupled inverters in write-only SRAM cell 10 connects to buffered read port 30.

Odd 1R1W cell 120 also has an L-shape because buffered read port 30’ is half the pitch of write-only SRAM cell 10’. Signal DOB from the cross-coupled inverters in write-only SRAM cell 10’ connects to buffered read port 30’. Two buffered read ports 30, 30’ fit in the same pitch as one write-only SRAM cell 10.

1R1W cells 110, 120 have interlocking L-shaped layouts that permit two cells to fit into a rectangle. The rectangular pair of cells 110, 120, rather than the individual L-shaped cells 110, 120, can be more easily arrayed into a larger memory.

FIG. 6 shows a simplified layout of an even-odd pair of 1R1W cells for a non-stacked process. Even 1R1W cell 110 has write-only SRAM cell 10 on top and buffered read port 30 in the center left, while odd 1R1W cell 120 has write-only SRAM cell 10’ on the bottom and buffered read port 30’ in the center right, as also shown in FIG. 5. 1R1W cells 110, 120 together form a rectangle having an interlocking pair of cells, despite their L-shapes. The interlocking L shapes can eliminate wasted space for dummy transistors.

At the top of FIG. 6, write-only SRAM cell 10 has p-channel transistors 12, 20, 22, 14 formed in p-type diffusion 80. These transistors are at locations where vertical polysilicon lines 720, 722 cross p-type diffusion 80. The polysilicon gates of transistors 12, 14 are connected together by metal M0 line 740 (dashed horizontal metal line) to via 90 and to word line WRLB, while the drains of transistors 12, 14 in p-type diffusion 80 are contacted to metal MD lines 730 and vias to bit lines DINE, DINEB.

Polysilicon lines 720, 722 and diffusion-contacting metal MD lines 730 both run vertically in the layout, while metal M0 lines 740 run horizontally. The lowest metal layer is diffusion-contacting metal MD lines 730 which run vertically in the cell layout and are parallel to polysilicon lines 720, 722. Metal M0 lines 740 are shown as dashed lines running horizontally and are above diffusion-contacting metal MD lines 730 and polysilicon lines 720, 722. Vias can connect M0 to upper metal layers M1, M2, etc. These upper metal layers are not shown, but may carry select signals WRL, WRLB, RDL, and RDLB in the vertical (x, row) direction and data signals DINE, DINEB, DINO, DINOB, DLE, and DLO in the horizontal (y, column) direction for an array of the rotated cell layout.

The p-type diffusion 80 node between transistors 12, 20 can be contacted to a diffusion-contacting metal MD line 730 that also contacts n-type diffusion 82 between n-channel transistors 16, 24. A metal M0 line 740 jumps over polysilicon line 722 to contact polysilicon line 720 that forms the gates of transistors 22, 26. This forms the cross-coupling of the SRAM internal true data node D.

The node between transistors 20, 22 in p-type diffusion 80 can be connected to power VDD while the node between transistors 24, 26 in n-type diffusion 82 can be connected to ground VSS.

The vertical polysilicon line 722 to the gates of transistors 20, 24 is extended downward from write-only SRAM cell 10 into buffered read port 30 to form the gates of transistors 32, 36. Thus no metal connection is required for the intra-cell SRAM data connection DEB to buffered read port 30. This poly connection reduces cell layout complexity.

Optional metal line 70 connects together the drains of transistors 32, 36. The gates of transistors 34, 74 are connected to read select line RDLB while the gates of transistors 38, 78 are connected to read select line RDL. The drains of transistors 34, 38 connect to data line DLE for buffered read port 30. The drains of transistors 74, 78 connect to data line DLO for buffered read port 30’.

For buffered read ports 30, 30’, p-type diffusion 84 forms p-channel transistors 32, 34, 72, 74, with VDD tapped between transistors 32, 72. N-type diffusion 88 forms n-channel transistors 36, 38, 76, 78, with VSS tapped between transistors 36, 76.

At the bottom, write-only SRAM cell 10’ has p-type diffusion 80’ with p-channel transistors 42, 44, 50, 52, and n-type diffusion 82’ with n-channel transistors 46, 48, 54, 56. The polysilicon gates of transistors 50, 54 is node DOB that is extended upward to form the gates of transistors 72, 76 in buffered read port 30’.

Higher levels of metal can carry word select lines WRL, WRLB, RDL, RDLB in the vertical direction (WL) in the rotated rows, and can carry data and bit lines DINE, DINEB, DLE, DLO, DINO, DINOB in the horizontal direction (BL) in the rotated columns. Note that there is one row but two columns: one even column (DINE, DINEB, DLE), and one odd column (DINO, DINOB. DLO) for every pair of 1R1W cells 110, 120.

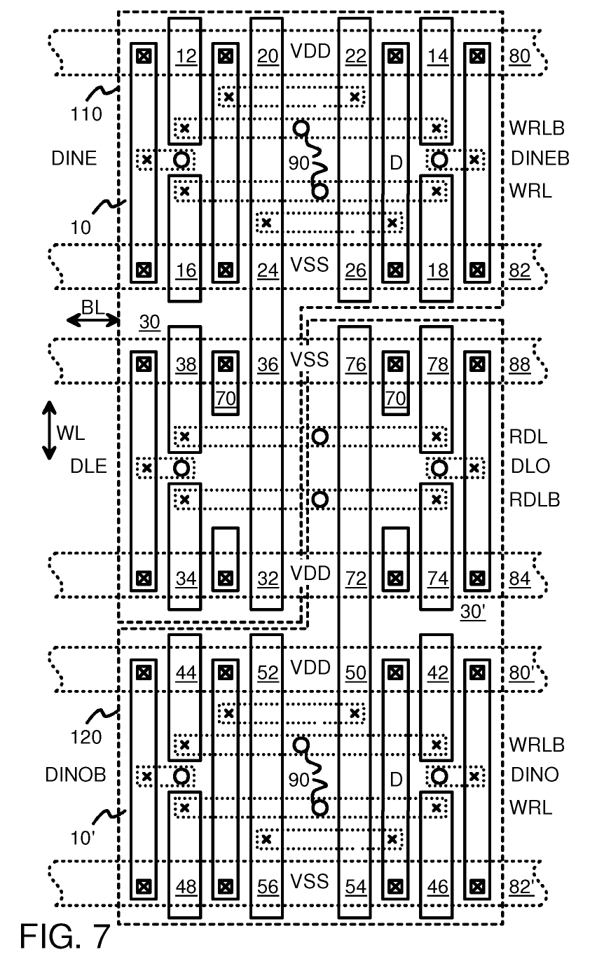

FIG. 7 shows an alternative layout without the metal short line in the buffered read port. Optional metal line 70 on the lowest MD metal layer in buffered read port 30 has been cut so that buffered read port 30 has a tri-state inverter rather than a transmission gate.

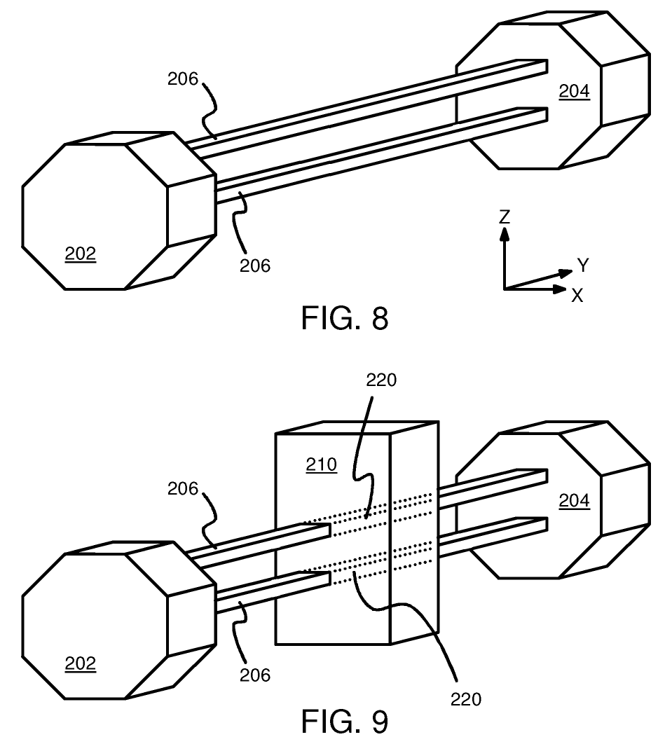

FIG. 8 shows 3D structures made from semiconductor materials that form transistor channels between source and drain regions. Transistors 12-56 in 1R1W cells 110, 120 can be standard planar transistors, finFETs, Gate-All-Around (GAA), nanosheets, ribbon FETs, Complementary FET (CFET) devices, or other transistor device types.

In FIG. 8, the core of a GAA transistor is shown, without the gate or metal connections. Source 202, drain 204, and semiconductor ribbons 206 are all formed from a semiconductor material. There may be multiple semiconductor ribbons 206 that each can form a conducting channel. Semiconductor ribbons 206 can be nanosheets or ribbons of semiconductor channel material, such as lightly doped silicon, germanium, or other semiconductor materials and mixtures.

FIG. 9 shows a Gate-All-Around (GAA) transistor. Gate 210 can be polysilicon, silicide, and have multiple layers of gate and metallic materials. Gate 210 completely surrounds semiconductor ribbons 206. Channels 220 of the transistor are formed where semiconductor ribbons 206 pass through gate 210. The voltage applied to gate 210 can control conduction through the channel portions of semiconductor ribbons 206 between source 202 and drain 204.

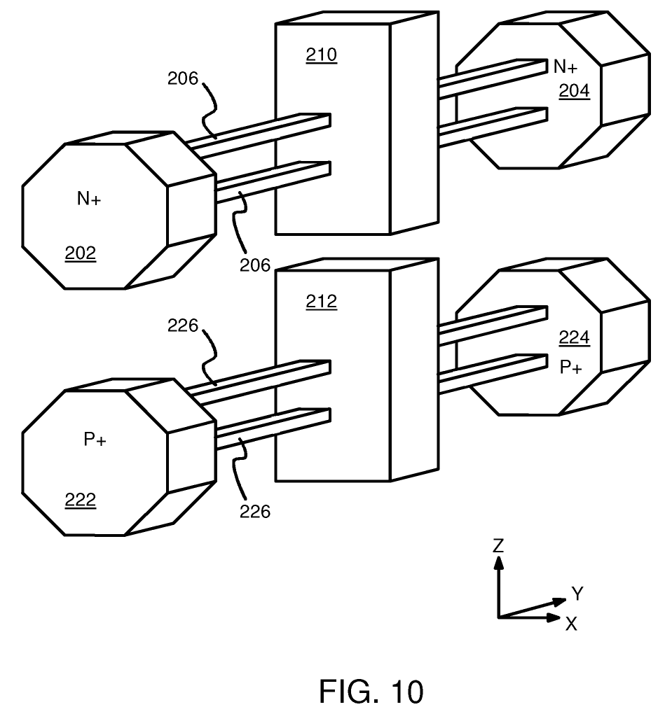

FIG. 10 shows stacked GAA transistors. Advanced processes such as Complementary FET (CFET) stack two transistors on top of each other in the Z direction. Thus two transistors can occupy the same area as one transistor in non-stacked processes.

Source 202 and drain 204 are n+ doped and form the source and drain of an n-channel transistor where semiconductor ribbons 206 pass through gate 210. Directly beneath this n-channel transistor is a p-channel transistor formed by p+ doped source 222 and p+ doped drain 224 that have semiconductor ribbons 226 in between. Gate 212 controls current through semiconductor ribbons 226.

Semiconductor ribbons 206 can have a light n-type doping for the upper n-channel transistor, while semiconductor ribbons 226 can have a light p-type doping for the lower p-channel transistor.

Gates 210, 212 can be separated by an insulating layer when the p-channel and n-channel transistors have different gate nodes, such as for pass transistors 12, 16, or can be connected together, such as for inverter transistors 20, 24.

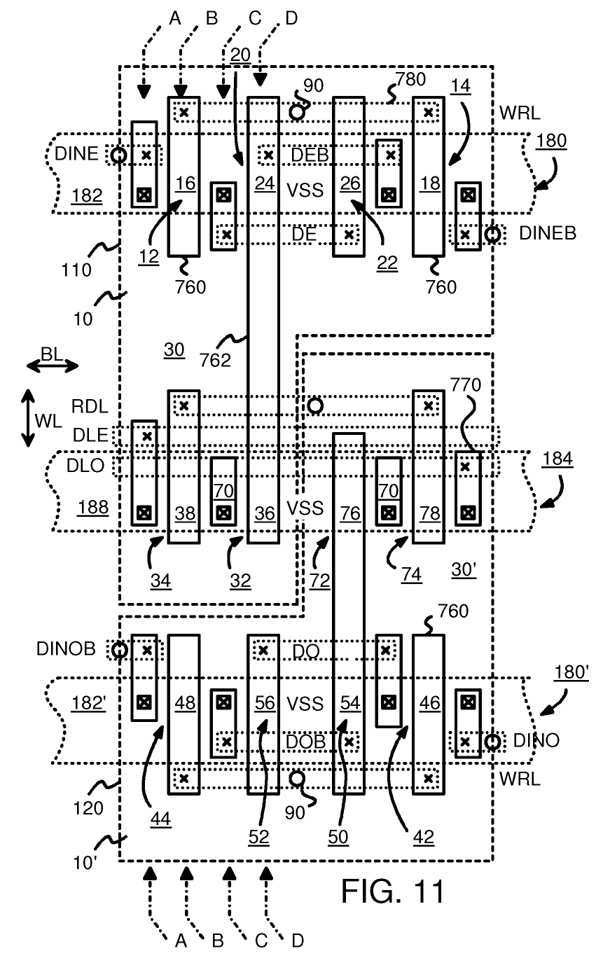

FIG. 11 is a simplified layout of the even-odd pair of 1R1W cells for a stacked-transistor process. Stacked transistors such as shown in FIG. 10 allow p-channel and n-channel transistors to be stacked directly on top of each other. For example, n-channel pass transistor 16 is stacked directly over p-channel pass transistor 12, and both have drains connecting to bit line DINE by metal contacts to MD and MDB metal layers that connect to higher metal layers to DINE lines across the array. The gates of pass transistors 12, 16 are separated and connect to WRL for n-channel pass transistor 16 and to WRLB for p-channel pass transistor 12. The gates of n-channel pass transistors 16, 18 are connected together by metal M0 lines 780 that run horizontally in the cell layout, and through via 90 to an upper metal line carrying WRL along the row in the array.

Polysilicon line 762 forms the gates of p-channel transistor 20 and n-channel transistor 24 in the cell inverter and extends downward into buffered read port 30 to form the gates of p-channel transistor 32 and n-channel transistor 36. Optional metal line 70 can include a contact to p-type diffusion 180 using lower diffusion-contacting metal MDB and a contact to n-type diffusion 182 using upper diffusion-contacting metal MD, and a via or vertical metal structure between the MD and MDB layers, which are stacked on top of each other.

The stacked process can have two diffusion-contacting metal layers. Upper diffusion-contacting metal MD contacts n-type diffusion 182 that forms the sources and drains of n-channel transistors 16, 18, 24, 26, while lower diffusion-contacting metal MDB contacts p-type diffusion 180 that forms the sources and drains of p-channel transistors 12, 14, 20, 22. Metal layers MD and MDB are at different Z levels and can cross each other or be directly over each other.

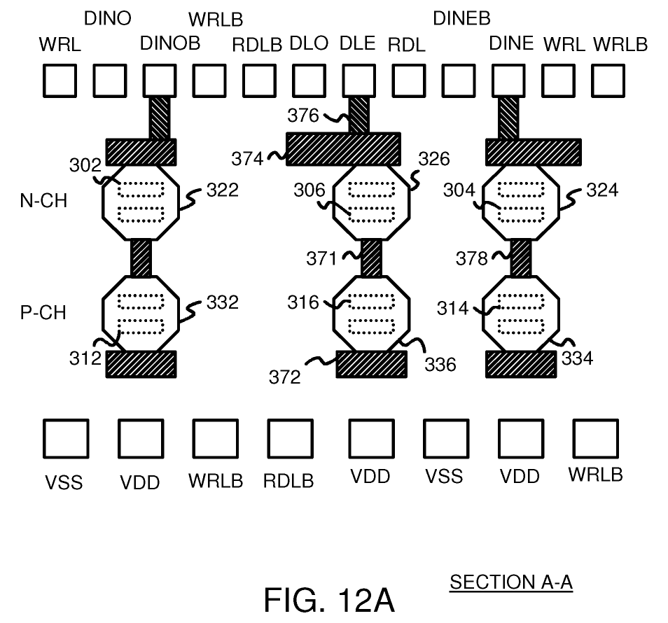

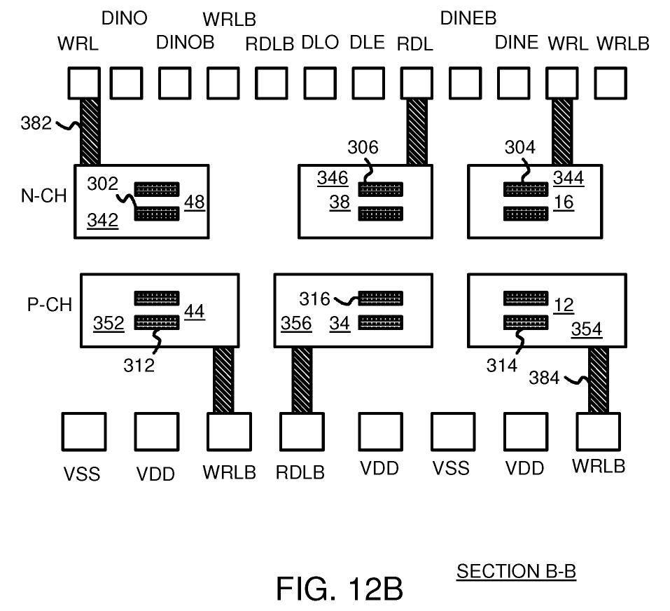

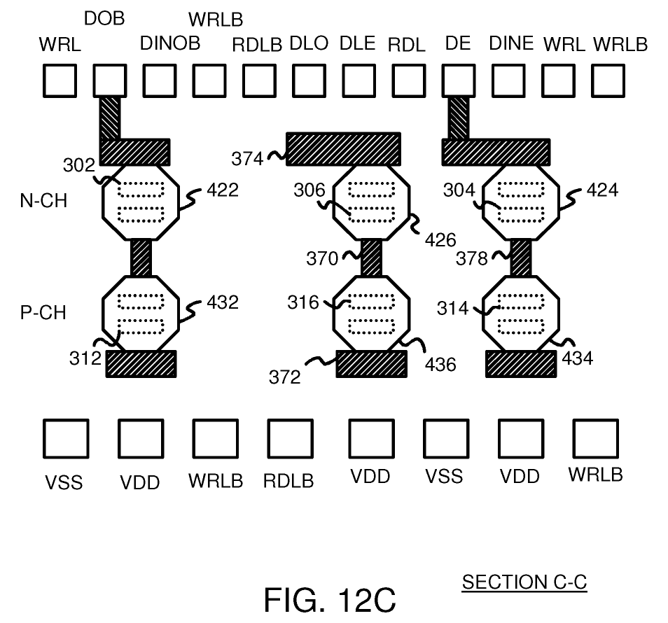

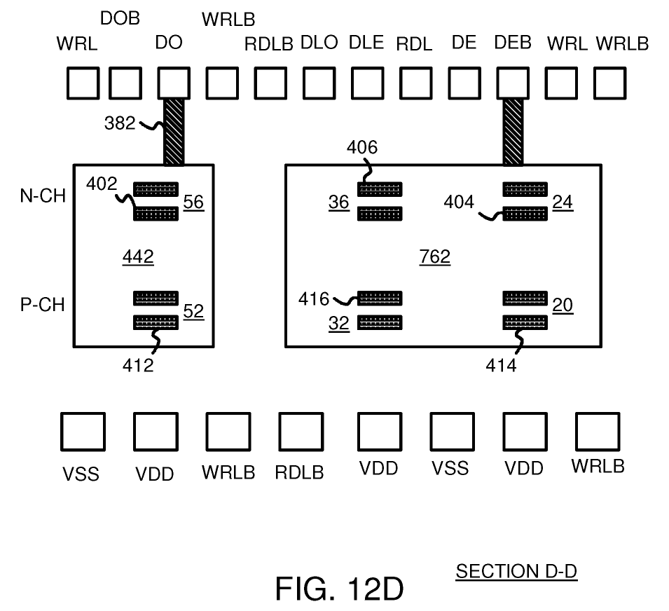

The stacked process can have two M0 metal layers. Upper metal M0 is shown as dashed horizontal lines in FIGS. 11 and by the squares at the top of FIGS. 12-13 and may have vias to upper diffusion-contacting metal MD, and vias to other upper metal layers M1, M2, etc. Lower metal M0B may have vias to lower diffusion-contacting metal MDB, and vias to other metal layers such as backside or frontside metal layers. Lower metal M0B is shown by the squares at the bottom of FIGS. 12-13 and is not shown in FIG. 11.

The polysilicon gates of n-channel pass transistors 16, 18 are connected together by metal M0 line 780 (dashed horizontal metal line) to via 90 and to word line WRL, while the drains of transistors 16, 18 in n-type diffusion 182 are contacted to metal MD lines and vias to bit lines DINE, DINEB. The polysilicon gates of p-channel pass transistors 12, 14 are connected together by a metal M0B line (underneath metal MD line 780) to another via and to word line WRLB, while the drains of transistors 12, 14 in p-type diffusion 180 are contacted by metal vias to the drains of transistors 16, 18 in n-type diffusion 182.

Polysilicon lines 762, etc. and diffusion-contacting metal MD lines and MDB lines run vertically in the layout, while metal M0 lines 780 run horizontally. Diffusion-contacting metal MD, and MDB lines run vertically in the cell layout and are parallel to polysilicon lines. Metal M0 lines 780 are shown as dashed lines running horizontally and are above diffusion-contacting metal MD, MDB and polysilicon lines. Vias can connect M0 to upper metal layers M1, M2, etc. These upper metal layers are not shown, but may carry select signals WRL, WRLB, RDL, and RDLB in the vertical (x, row) direction and data signals DINE, DINEB, DINO, DINOB, DLE, and DLO in the horizontal (y, column) direction for an array of the rotated cell layout.

A metal M0 line jumps over polysilicon line 762 to contact the polysilicon line that forms the gates of transistors 22, 26. This forms the cross-coupling of the SRAM internal true data node D.

The node between transistors 20, 22 in p-type diffusion 180 can be connected to power VDD while the node between transistors 24, 26 in n-type diffusion 182 can be connected to ground VSS. Backside metal layers and through-hole vias can be used for VDD and VSS for a process technology that supports backside power distribution.

Higher levels of metal can carry word select lines WRL, WRLB, RDL, RDLB in the vertical direction (WL) in the rotated rows, and can carry data and bit lines DINE, DINEB, DLE, DLO, DINO, DINOB in the horizontal direction (BL) in the rotated columns. Note that there is one row but two columns: one even column (DINE, DINEB, DLE), and one odd column (DINO, DINOB. DLO) for every pair of 1R1W cells 110, 120.

FIGS. 12A-D are cross sectional slices through the pair of 1R1W cells of FIG. 11.

FIG. 12A is a cross-sectional slice through the bit-line sources of the stacked transistors in the pair of 1R1W cells. FIG. 12A is a cross section through slice A-A that is marked on the left of FIG. 11, looking from the right side toward the left, through the sources of transistors 12, 16, 34, 38, 44, 48.

Source 332 is the source of p-channel transistor 44 and connects to nano-wire or ribbon channels 312 that are perpendicular to the plane of FIG. 12A. Source 322 is the source of n-channel transistor 48 and connects to channels 302. These are the odd cell pass transistors.

Source 336 is the source/drain of p-channel transistor 34 and connects to channels 316. Source 326 is the source/drain of n-channel transistor 38 and connects to channels 306. These are the odd cell read-port transistors. Metal 371 is a vertical metal line that vertically connects sources 326, 336 together.

Source 334 is the source of p-channel transistor 12 and connects to channels 314. Source 324 is the source of n-channel transistor 16 and connects to channels 304. These are the even cell pass transistors. Metal 378 is a vertical metal line that vertically connects sources 324, 334 together.

Metal 374 is the MD metal that contacts source 326, while via metal 376 connects diffusion metal MD to M0 metal for read data line DLE.

FIG. 12B is a cross-sectional slice through the gates of the stacked transistors in the pair of 1R1W cells. FIG. 12B is a cross section through slice B-B marked on the left of FIG. 11, looking from the right side toward the left, through the gates and channels of transistors 12, 16, 34, 38, 44, 48.

Gate 352 is the gate of p-channel transistor 44 and surrounds channels 312. Gate 352 is connected by via metal to metal M0 line for WRLB. Gate 342 is the gate of n-channel transistor 48 and surrounds channels 302. Gate 342 is connected by via metal 382 to metal M0 line for WRL.

Gate 356 is the gate of p-channel transistor 34 and surrounds channels 316. Gate 356 is connected by via metal to metal M0 line for RDLB. Gate 346 is the gate of n-channel transistor 38 and surrounds channels 306. Gate 346 is connected by via metal to metal M0 line for RDL.

Gate 354 is the gate of p-channel transistor 12 and surrounds channels 314. Gate 354 is connected by via metal 384 to metal M0 line for WRLB. Gate 344 is the gate of n-channel transistor 16 and surrounds channels 304. Gate 344 is connected by via metal to metal M0 line for WRL.

FIG. 12C is a cross-sectional slice through the cross-coupled inverter drains of the stacked transistors in the pair of 1R1W cells. FIG. 12C is a cross section through slice C-C that is marked on the left of FIG. 11, looking from the right side toward the left, through the drains of transistors 12, 16, 34, 38, 44, 48. These are also the drains of transistors 20, 24, 32, 36, 52, 56.

Drain 432 is the source/drain of p-channel transistors 44, 52 and connects to nano-wire or ribbon channels 312 that are perpendicular to the plane of FIG. 12C. Drain 422 is the source/drain of n-channel transistors 48, 56 and connects to channels 302. These are the odd cell pass transistors and inverter.

Drain 436 is the source/drain of p-channel transistors 32, 34 and connects to channels 316. Drain 426 is the source/drain of n-channel transistors 36, 38 and connects to channels 306. These are the odd cell read-port and data transistors.

Optional metal 370 shorts drains 436, 426 together for the transmission gate (FIG. 2, nodes A, B shorted), or is absent for the tri-state read port (FIG. 3, nodes A, B separate).

Drain 434 is the source/drain of p-channel transistors 12, 20 and connects to channels 314. Drain 424 is the source/drain of n-channel transistors 16, 24 and connects to channels 304. These are the even cell pass and inverter transistors. Metal 378 is a vertical metal line that vertically connects drains 324, 334 together.

FIG. 12D is a cross-sectional slice through the gates of the stacked transistors in the pair of 1R1W cells. FIG. 12D is a cross section through slice D-D marked on the left of FIG. 11, looking from the right side toward the left, through the gates and channels of transistors 20, 24, 32, 36, 52, 56.

Gate 442 is the gate of p-channel transistor 52 and n-channel transistor 56 and surrounds channels 402, 412. Gate 442 is connected by via metal 382 to metal M0 line for the odd data line DO.

Polysilicon line 762 is the gate of p-channel transistors 20, 34 and n-channel transistors 24, 36 and surrounds channels 404, 406, 414, 416. Polysilicon line 762 is connected by via metal to metal M0 line for the inverse internal cell node DEB.

In some stacked processes, the GAA gates for the n-channel and p-channel transistors can be a single block of gate material. Some stacked processes may have separate blocks of gate material for n-channel and p-channel transistors, and a metal line (not shown) can be added to short the p-channel and n-channel gates.

### ALTERNATE EMBODIMENTS

Several other embodiments are contemplated by the inventors. For example many combinations and variations of the metal interconnect and routing are possible. The layouts shown in FIGS. 6-12 are simplified and not drawn to scale. Additional layers and features may be present in the actual layout. For example, additional metal lines may be added for power and ground connections, and additional metal interconnect layers may be present. Gates may have smaller features such as length or pitch that drain metal connections.

The p-channel transistors in write-only SRAM cell 10 can be laid out in a PMOS line segment that is about double the length of a PMOS line segment that the p-channel transistors in buffered read port 30 are laid out along. The sources, drains, and conducting channels of the p-channel transistors tend to fall along a line, although with nanosheets and multi-channel transistors some of the channels may be parallel but slightly offset from this line, so they still fall along this PMOS line in a more general sense. For vertically stacked transistor processes such as CFET, an NMOS line segment that the n-channel transistors fall along is directly above the PMOS line segment that the p-channel transistors fall along, while for non-stacked planar, FinFET, and GAA processes these PMOS and NMOS line segments can be both in a same plane that is parallel to the surface of the Integrated Circuit (IC).

The simplified layouts shown are not drawn to scale. For example, gates can be much smaller than metal lines in some processes, but are shown as approximately the same width in these examples for easier illustration. Also, metal-to-diffusion contacts may extend the full width of the diffusion rather than the limited box areas shown. Various other spacings and features may be scaled to fit design rules for various specific semiconductor processes. Lines can refer to metal rectangles rather than to mathematical lines of zero width. These metal and polysilicon lines can have a width and may have jogs or bends rather than be perfectly straight.

While polysilicon gates have been described, the gate material may have multiple layers and include metals, silicide, and other materials rather than polysilicon.

Several other embodiments are contemplated by the inventors. A multiport SRAM cell and its macro architecture are designed to allow deep dynamic voltage and power scaling in advanced node FinFETs/GAA technologies. Only a single power supply is required for a wide range of Process, supply Voltage, Temperature (PVT) conditions. Power consumption reduction of 10x may be achieved by a combination of a reduced power supply voltage and lowered operating clock frequency. In an asynchronous read cell/macro variety the address alignment with a clock is not required for a high-speed access. The 1R1W cell topology can be expanded by adding 1, 2, 3, or more additional read ports. Layout footprint is minimized for advanced node CMOS technologies because NMOS and PMOS transistor counts are balanced in the memory cells.

Write-only RAM cell 10 can be attached to more than one buffered read port. The write port could also be used for reading by adding sense amplifiers to the bit lines. Reading after a write to the cell could be performed over the write bit lines for a read-modify-write cycle or for verifying a write.

While write-only RAM cell 10 with pull-up p-channel transistors 20, 22 in the cell latch have been described, pull-up resistors could replace p-channel transistors 20, 22. Various layouts of the SRAM cell are possible.

While operation of the SRAM cell has been described, various modifications can be made. The sense amplifier could be inverted and sense high-going rather than low-going bit lines. A simplified sense amplifier such as a single-ended sense buffer could be used. Using a simple single-ended sense amplifier can reduce costs for applications that do not have a strict timing requirement.

Address inputs, timing signal inputs, and other inputs such as for power down or de-selection could be combined by logic within the decoders and other logic upstream to the final inverting buffers. A controller could generate various timing signals from a clock or an access request signal to obtain desired waveforms. The simple blocks of FIGS. 7, 9 may be considered to be simplifications of more complex decoders and gating logic in a real memory device. Some memory architectures may not use row and column decoders of an address, such as a first-in-first-out (FIFO) that has an array of the write-only RAM cell 10 and buffered read port 30 but uses shift registers with one high bit and the other bits low in place of the row decoders or column decoders.

Column muxing is possible, with different mux ratios such as 2:1, 8:1, etc. No column muxing within a bank is a simpler variation. Various architectures can be employed, such as a standard array of rows and columns, a folded bit line architecture, sub-array architectures, split rows or split columns, dummy rows, or dummy columns, etc. Columns or rows may be split or fold over such as where two physical columns have their bit lines connected together as a single column from a schematic viewpoint. Arbitrary memory sizes M x N and word lengths Q can be supported.

Various signals could be inverted. For example, the bit lines could be reset low rather than precharged high. The pre-initialized bit lines could be driven high by the selected cell rather than driven low. P-channel and n-channel transistors could be swapped. Inversions could be added or removed at various places, such as by swapping or crossing true and complement bit lines and mux lines, or adding or removing inverters or using non-inverting rather than inverting buffers.

Rather than using DEB, DOB as intra-cell interconnect, DE, DO could be used and inverse data lines used such as DLEB, DLOB.

The ground connection to the memory cells could connect to a back-bias generator that generates a body or bias voltage that is below ground. The muxing of columns may be much more complex, and there may be sub-arrays and selections of one sub-array and disabling of other sub-arrays. Masking logic may be added that could disable sensing or writing of certain bits within a multi-bit word.

The actual margin values, and the power supply VDD voltages can vary. Supply voltages can be scaled with process improvements and may be dynamically adjusted or switched in a system, such as to reduce over-heating when a temperature alarm is signaled, or when the system enters a low-power mode. A voltage regulator or filter might be added to VDD, or the natural capacitances of the memory cells may be sufficient to regulate VDD.

Many layouts of the cell are possible within the spirit of the invention, and those skilled in the art will be able to make many modifications.

The n-channel access transistor has been described as having a source diffusion connected to the bit line and a drain diffusion connected to the cross-coupled inverters. However, those skilled in the art will recognize that MOS transistors are bi-directional in nature and the source and drain diffusions are physically indistinguishable. For normal bit-line biasing, the source terminal of an n-channel transistor has a lower voltage or potential than the drain terminal, but if the applied voltage is reversed then the source and drain terminals can reverse with the drain becoming the source and vice-versa. Thus the terms “source” and “drain” are used interchangeably, and for both p-channel and n-channel transistors.

Additional leaker devices such as resistors and small transistors could be added. Parasitic capacitances and resistances may be used from some components, depending on the process and device sizes used. Bias, VDD, and voltage values may vary somewhat due to process, temperature, and design variances.

While descriptions of current flows and operations have been presented, these are theoretical, and the theories may be incomplete or even incorrect. Especially for small devices, currents may flow in unusual ways and using mechanisms that have not yet been thoroughly researched and understood. Second and third order effects may also be present.

Cutouts in diffusion and other regions may be used. Other shapes and physical layouts may be substituted, such as intermingled fingers. For FinFET transistors, fins could intersect other fins, bend, or have various macro geometries and layouts. GAA also has many possibilities and variations.

Devices may be implemented using n-channel, p-channel, or bipolar transistors, or junctions within these transistors, or carbon nanotubes. A capacitor could be attached to a resistance to provide an R-C time delay, or more complex circuits such as active triggering circuits may be added. In some embodiments, high-voltage transistors may be used rather than low-voltage transistors with appropriate bias conditions. The gate lengths and spacings can be increased to provide better protection from damage.

Different transistor, capacitor, resistor, and other device sizes can be used, and various layout arrangements can be used, such as multi-leg, ring, doughnut, or irregular-shape transistors. Additional taps, guard rings, transistors, and other components may be added. More than one power supply may be used.

The background of the invention section may contain background information about the problem or environment of the invention rather than describing prior art by others. Thus, inclusion of material in the background section is not an admission of prior art by the Applicant.

Many variations of IC semiconductor manufacturing processes are possible. Various materials may be used. Additional process steps may be added, such as for additional metal layers or for other transistor types or modification of standard complementary metal-oxide-semiconductor (CMOS) transistors when the transistors are integrated onto a larger device. While complementary metal-oxide-semiconductor (CMOS) transistors have been described, other kinds of transistors could be substituted for some embodiments, such as n-channel only, p-channel only when the output swing can be limited, or various alternate transistor technologies such as Bipolar or BiCMOS. The CMOS process may be a Fin Field-Effect Transistor (FinFET) process, a Gate-All-Around (GAA) process, a Complementary FET (CFET) process, or other extensions and variations.

Terms such as up, down, above, under, horizontal, vertical, inside, outside, are relative and depend on the viewpoint and are not meant to limit the invention to a particular perspective. Devices may be rotated so that vertical is horizontal and horizontal is vertical, so these terms are viewer dependent. Rows can be vertical and columns can be horizontal when the orientation is rotated from an orientation with horizontal rows and vertical columns. The Integrated Circuit may be flipped over by the viewer so that up is down and down is up.

The background of the invention section may contain background information about the problem or environment of the invention rather than describe prior art by others. Thus inclusion of material in the background section is not an admission of prior art by the Applicant.

Any methods or processes described herein are machine-implemented or computer-implemented and are intended to be performed by machine, computer, or other device and are not intended to be performed solely by humans without such machine assistance. Tangible results generated may include reports or other machine-generated displays on display devices such as computer monitors, projection devices, audio-generating devices, and related media devices, and may include hardcopy printouts that are also machine-generated. Computer control of other machines is another tangible result.

Any advantages and benefits described may not apply to all embodiments of the invention. When the word "means" is recited in a claim element, Applicant intends for the claim element to fall under 35 USC Sect. 112, paragraph 6. Often a label of one or more words precedes the word "means". The word or words preceding the word "means" is a label intended to ease referencing of claim elements and is not intended to convey a structural limitation. Such means-plus-function claims are intended to cover not only the structures described herein for performing the function and their structural equivalents, but also equivalent structures. For example, although a nail and a screw have different structures, they are equivalent structures since they both perform the function of fastening. Claims that do not use the word “means” are not intended to fall under 35 USC Sect. 112, paragraph 6. Signals are typically electronic signals, but may be optical signals such as can be carried over a fiber optic line.

The foregoing description of the embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

1. An array of multi-port memory cells, a multi-port memory cell in the array of multi-port memory cells comprising a writable cell and a buffered read port, wherein the writable cell comprises: a first PMOS row of p-channel transistors, situated along a first PMOS line segment, in a sequence of a first p source connected to a first bit line, a first p gate over a first p channel, a first p drain, a first inverter p gate over a first inverter p channel, a p source connected to a power supply, a second inverter p gate over a second inverter p channel, a second p drain, a second p gate over a second p channel, and a second p source connected to a second bit line; a complement crossover metal line, parallel to the first PMOS line segment, for connecting the first p gate to the second p drain; a true crossover metal line, parallel to the first PMOS line segment, for connecting the second p gate to the first p drain; a first NMOS row of n-channel transistors, situated along a first NMOS line segment that is parallel to the first PMOS line segment, in a sequence of a first n source connected to the first bit line, a first n gate over a first n channel, a first n drain, a first inverter n gate over a first inverter n channel, an n source connected to a ground supply, a second inverter n gate over a second inverter n channel, a second n drain, a second n gate over a second n channel, and a second n source connected to the second bit line; a first bit line source metal that connects the first p source to the first n source with a via connecting to a first bit line in an upper metal layer; a first drain metal that connects the first p drain to the first n drain; a second bit line source metal that connects the second p source to the second n source with a via connecting to a second bit line in an upper metal layer; a second drain metal that connects the second p drain to the second n drain; a write select metal line, parallel to the first PMOS line segment, for connecting a write select signal in an upper metal layer to the first n gate and to the second n gate; an inverse write select metal line, parallel to the first PMOS line segment, for connecting an inverse write select signal in an upper metal layer to the first p gate and to the second p gate; wherein the first inverter n gate is connected to the first inverter p gate; wherein the second inverter n gate is connected to the second inverter p gate; wherein the buffered read port comprises: a data PMOS row of p-channel transistors, situated along a data PMOS line segment that is parallel to the first PMOS line segment, in a sequence of a data p source connected to a first data line, a read p gate over a read p channel, a data p drain, a data p gate over a data p channel, and a tap p source connected to the power supply, a data NMOS row of n-channel transistors, situated along a data NMOS line segment that is parallel to the first NMOS line segment, in a sequence of a data n source connected to the first data line, a read n gate over a read n channel, a data n drain, a data n gate over a data n channel, and a tap n source connected to the ground supply, a data line source metal that connects the data p source to the data n source with a via connecting to a data line in an upper metal layer; a read select metal line that connects the read n gate to a via connecting to a read select signal line in an upper metal layer; and an inverse read select metal line that connects the read p gate through a via to an inverse read select signal line in an upper metal layer.

2. The array of multi-port memory cells of claim 1 wherein the data PMOS line segment has a length that is less than a length of the first PMOS line segment; wherein the writable cell occupies a greater area than the buffered read port.

3. The array of multi-port memory cells of claim 2 wherein a total number of p-channel transistors equals a total number of n-channel transistors in the multi-port memory cell.

4. The array of multi-port memory cells of claim 3 wherein the writable cell is laid out in a first rectangle having a first area; wherein the buffered read port is laid out in a second rectangle having a second area that is smaller than the first area; wherein the second rectangle abuts the first rectangle; wherein the data p gate, the data n gate, the first inverter p gate, and the first inverter n gate are connected together between the writable cell and the buffered read port; wherein the multi-port memory cell has an L shaped area footprint with a wider portion having the writable cell in the first rectangle and a narrower portion having the buffered read port in the second rectangle; wherein the first rectangle and the second rectangle form an L shape; wherein the multi-port memory cell has an L shaped area footprint that allows two buffered read ports to occupy a pitch of a single writable cell.

5. The array of multi-port memory cells of claim 3 wherein the multi-port memory cells are arrayed by aligning the data PMOS line segment of an even multi-port memory cell with the data PMOS line segment of an odd multi-port memory cell so that the data PMOS line segments of the even and odd cells are in a same line;
wherein an even-odd pair of the multi-port memory cell are interlocked by aligning data PMOS line segments and by aligning data NMOS line segments;
wherein the data PMOS line segments of the even multi-port memory cell and the odd multi-port memory cell are aligned and are between the first PMOS line segment of the even multi-port memory cell and the first PMOS line segment of the odd multi-port memory cell, wherein the data PMOS row of p-channel transistors is laid out between the first PMOS row of p-channel transistors of the even multi-port memory cell and the first PMOS row of p-channel transistors of the odd multi-port memory cell; wherein the data NMOS row of n-channel transistors is laid out between the first NMOS row of n-channel transistors of the even multi-port memory cell and the first NMOS row of n-channel transistors of the odd multi-port memory cell.

6. The array of multi-port memory cells of claim 5 wherein the data PMOS line segment has a length that is half of a length of the first PMOS line segment.

7. The array of multi-port memory cells of claim 3 further comprising: a polysilicon intra-cell interconnect comprising a single polysilicon block that forms the data p gate, the data n gate, the first inverter p gate, and the first inverter n gate, whereby the writable cell and the buffered read port are connected together by being formed from the single polysilicon block; whereby metal intra-cell interconnect is avoided by using the single polysilicon block.

8. The array of multi-port memory cells of claim 3 further comprising:
an option metal line that connects the data p drain to the data n drain to form a read transmission gate.

9. The array of multi-port memory cells of claim 3 wherein a pair of the multi-port memory cells is laid out in a sequence of: the first PMOS row of p-channel transistors for an even cell; the first NMOS row of n-channel transistors for the even cell; the data NMOS row of n-channel transistors for the even cell and the data NMOS row of n-channel transistors for an odd cell that are laid out along a same data NMOS line; the data PMOS row of p-channel transistors for the even cell and the data PMOS row of p-channel transistors for the odd cell that are laid out along a same data PMOS line; the first PMOS row of p-channel transistors for the odd cell; the first NMOS row of n-channel transistors for the odd cell.

10. The array of multi-port memory cells of claim 9 wherein the pair of the multi-port memory cells is arrayed to construct a memory array.

11. The array of multi-port memory cells of claim 3 wherein the first p gate surrounds the first p channel on three sides; wherein the first n gate surrounds the first n channel on three sides; wherein the p-channel transistors and the n-channel transistors are FinFET transistors.

12. The array of multi-port memory cells of claim 3 wherein the first p gate surrounds the first p channel on four sides; wherein the first n gate surrounds the first n channel on four sides; wherein the p-channel transistors and the n-channel transistors are Gate-All-Around (GAA) transistors.

13. The array of multi-port memory cells of claim 12 wherein the first NMOS line segment is parallel and above the first PMOS line segment, wherein the first n channel is vertically stacked above the first p channel; wherein the data NMOS line segment is parallel and above the data PMOS line segment, wherein the data n channel is vertically stacked above the data p channel; wherein the n-channel transistors are vertically stacked with the p-channel transistors.

14. A 12-transistor cell layout comprising: a writable cell having 4 p-channel transistors and 4 n-channel transistors arranged as a cross-coupled pair of inverters and a first transmission gate to a first bit line and a second transmission gate to a second bit line; a buffered read port having 2 p-channel transistors and 2 n-channel transistors that include data transistors having gates driven by an inverter in the cross-coupled pair of inverters and select transistors having gates driven by a read select signal, for driving data onto a data line; wherein the writable cell is laid out in a first rectangle and the buffered read port is laid out in a second rectangle that abuts the first rectangle; wherein two second rectangles fit into a pitch of the first rectangle; wherein the first rectangle and the second rectangle form an L-shaped area; wherein an even instance of the writable cell is laid out in a first column; wherein an even instance of the buffered read port and an odd instance of the buffered read port are laid out in a second column that is adjacent to the first column; wherein an odd instance of the writable cell is laid out in a third column that is adjacent to the second column and separated from the first column by the second column, whereby even and odd cell instances of cells having the L-shaped area are laid out in an interlocking pattern.

15. The 12-transistor cell layout of claim 14 wherein the n-channel transistors have gates that surround channels, wherein the n-channel transistors are Gate-All-Around (GAA) transistors;
wherein the p-channel transistors have gates that surround channels, wherein the p-channel transistors are Gate-All-Around (GAA) transistors.

16. A Static Random-Access Memory (SRAM) cell comprising: a write-only SRAM cell that comprises: a first pull-up transistor and a first pull-down transistor connected in series between a power supply and a ground, the first pull-up transistor and the first pull-down transistor connected at a first latch node; a second pull-up transistor and a second pull-down transistor connected in series between the power supply and the ground, the second pull-up transistor and the second pull-down transistor connected at a second latch node; wherein gates of the first pull-up transistor and of the first pull-down transistor are driven by the second latch node between the second pull-up transistor and the second pull-down transistor; wherein gates of the second pull-up transistor and of the second pull-down transistor are driven by the first latch node between the first pull-up transistor and the first pull-down transistor; a first n-channel pass transistor connected between the first latch node and a first write bit line, and having a gate connected to a write word line; a second n-channel pass transistor connected between the second latch node and a second write bit line, and having a gate connected to the write word line; a first p-channel pass transistor connected between the first latch node and the first write bit line, and having a gate connected to an inverse write word line; a second p-channel pass transistor connected between the second latch node and the second write bit line, and having a gate connected to the inverse write word line; a buffered read port that comprises: a buffer transistor with a gate connected to the second latch node from the write-only SRAM cell, and a channel that conducts current controlled by the gate; and a pass transistor having a gate connected to a read word line and a channel connected between the channel of the buffer transistor and a read bit line; wherein reading is performed by activating the read word line and sensing read data on the read bit line; wherein writing is performed by activating the write word line high and the inverse write word line low and driving input data onto the first write bit line and driving an inverse of the input data onto the second write bit line; wherein the buffered read port further comprises: a p-channel buffer transistor with a gate connected to the second latch node from the write-only SRAM cell, and a channel that conducts current between the power supply and a first read-port node; a p-channel pass transistor having a gate connected to an inverse read word line and a channel connected between first read-port node and the read bit line; wherein the buffer transistor further comprises a n-channel buffer transistor with the gate connected to the second latch node from the write-only SRAM cell, and the channel that conducts current between the ground and a second read-port node; wherein the pass transistor further comprises a n-channel pass transistor having the gate connected to the read word line and the channel connected between the second read-port node and the read bit line; wherein two instances of the buffered read port are laid out next to each other between an even instance of the write-only SRAM cell and an odd instance of the write-only SRAM cell; wherein an even instance of the buffered read port is con wherein an odd instance of the buffered read port is connected to the second latch node from the odd instance of the write-only SRAM cell; whereby a pair of the SRAM cell is laid out as a pair of L-shaped interlocked cells.

17. The SRAM cell of claim 16 further comprising: a gate extension of the gates of the first pull-up transistor and of the first pull-down transistor that are driven by the second latch node, the gate extension forming the gate of the p-channel buffer transistor and the gate of the n-channel buffer transistor; whereby the write-only SRAM cell and the buffered read port are connected by the gate extension without a metal jumper.

18. The SRAM cell of claim 16 further comprising: a metal line connected between the first read-port node and the second read-port node to short the first read-port node to the second read-port node; wherein the p-channel pass transistor and the n-channel pass transistor comprise a transmission gate.

19. The SRAM cell of claim 16 wherein the n-channel transistors have gates that surround channels, wherein the n-channel transistors are Gate-All-Around (GAA) transistors; wherein the p-channel transistors have gates that surround channels, wherein the p-channel transistors are Gate-All-Around (GAA) transistors.

20. The SRAM cell of claim 19 wherein the n-channel transistors are stacked vertically on top of the p-channel transistors, wherein the SRAM cell is constructed from Complementary Field-Effect Transistors (CFETs).
